(19) United States
(12) Patent Application Publication
(10) Pub. No.: US 2023/0172033 A1
(43) Pub. Date: Jun. 1, 2023

(54) PROCESSES FOR IMPROVING THIN-FILM ENCAPSULATION

(71) Applicant: Applied Materials, Inc., Santa Clara, CA (US)

(72) Inventors: Wen-Hao WU, San Jose, CA (US); Jrjyan Jerry CHEN, Campbell, CA (US)

(21) Appl. No.: 17/801,818

(22) PCT Filed: Feb. 2, 2021
(86) PCT No.: PCT/US2021/016243

§ 371 Date: Aug. 24, 2022

Related U.S. Application Data
(60) Provisional application No. 62/983,067, filed on Feb. 28, 2020.

(51) Int. Cl. H10K 59/80; H10K 59/65

(52) U.S. Cl. CPC H10K 59/873; H10K 59/65

(57) ABSTRACT

A method and apparatus for forming an encapsulation layer on an organic light emitting diode (OLED) patterned substrate are described. A sidewall planarization layer fills voids in a scalloped sidewall of a wall feature on the OLED patterned substrate. The sidewall planarization layer is cured in the same chamber as the deposition of the sidewall planarization layer. A barrier layer is formed on the sidewall planarization layer. The sidewall planarization layer provides a planarized surface for good adhesion of the barrier layer over the sidewall planarization layer which minimizes the possibility of defects to the OLED patterned substrate from moisture of oxygen penetrating the OLED patterned substrate.

### BACKGROUND

### Field

Embodiments of the invention generally relate to a method and apparatus for encapsulating organic light emitting diode device structures and wall features formed on an organic light emitting diode substrate.

### Description of the Related Art

Electronic devices that utilize displays, such as hand held devices, televisions, monitors and wrist watches and other display devices often utilize Organic light emitting diode (OLED) displays due to their faster response time, larger viewing angles, higher contrast, lighter weight, low power and amenability to flexible substrates such as compared to liquid crystal displays (LCD). However, as shown in FIG. 1, other accessory features related to the display device, such as camera lenses, speakers, and sensors are positioned in regions of the electronic device that are separate from a region that includes the OLED display. The need to separate the other accessory features from the display region undesirably reduces the size of the active display region. The current trend is for ever larger displays that utilize as much of the front of the electronic device's user facing surface as possible. Therefore, there is a need to integrate the additional electronic device accessory features into the OLED display to at least increase the size of the active display region. However, conventional processes and supporting structures used to integrate the accessory features into the display region of an electronic device often include processing artifacts, such as discussed in relation to FIGS. 4A-4B, that make the formed structure susceptible to moisture and oxygen degradation. Therefore, there is a need for a device structure and method of forming the same that resolves these issues.

### SUMMARY

In one embodiment, a method for encapsulating a structure on an OLED patterned substrate is provided. The method includes positioning an OLED patterned substrate into a plasma processing chamber, the OLED patterned substrate having a wall structure with at least one scalloped surface, depositing a sidewall planarization layer directly on the wall structure filling at least one of a plurality of voids along the at least one scalloped surface.

In another embodiment, a patterned substrate is provided. The substrate has a plurality of OLED devices formed on a surface of the substrate, at least one wall structure formed on the surface of the substrate, the wall structure having at least one scalloped surface. The wall structure further includes a sidewall planarization layer disposed over the wall structure and filling at least one of a plurality of voids along the at least one scalloped surface.

In yet another embodiment, a plasma processing chamber for forming an encapsulating structure on an OLED patterned substrate is provided. The plasma processing chamber having a substrate support disposed within a processing region of the plasma processing chamber, a showerhead disposed within the processing region opposite the substrate support, a gas source coupled to the showerhead, an ampoule configured to provide liquid precursors to the chamber, and a controller configured to control a process for forming an encapsulation structure on the patterned substrate. The process for forming the encapsulation structure on the patterned substrate includes positioning an OLED patterned substrate into the plasma processing chamber, the OLED patterned substrate having a wall structure with at least one scalloped surface, and depositing a sidewall planarization layer directly on the wall structure filling at least one of a plurality of voids along the at least one scalloped surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a conventional handheld display device with electronic features separate from the OLED display.

FIG. 2A is a schematic top view of a handheld device with electronic features integrated into a region of the OLED display.

FIG. 2B is a schematic cross-sectional view formed along a cutting plane that extends through the integrated device accessory feature shown in FIG. 2A.

FIG. 3A is a top plan view of a section of the OLED patterned substrate used in FIG. 2A.

FIG. 3B is a schematic cross-section view formed along a cutting plane that extends through a portion of the OLED patterned substrate shown in FIG. 3A.

FIG. 4A is a schematic cross-sectional view of a wall portion shown in FIG. 3B.

FIG. 4B is a schematic cross-sectional view of a conventional encapsulated wall portion formed from the wall portion shown in FIG. 4A.

FIG. 5 is a schematic, cross-sectional view of a PECVD apparatus chamber that may be used to perform the methods described herein.

FIG. 6 is a flow diagram of a method of encapsulating features on the OLED substrate in accordance with one embodiment of the disclosure.

FIGS. 7A-7C illustrate schematic cross-sectional views of the OLED substrate features during different stages of the method of FIG. 8.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

FIG. 1 is a schematic top view of a conventional handheld display device with electronic device accessory features separate from the OLED display. In this example, the handheld display device is a mobile phone. The display device 100 includes a display region 110 and camera lens 120 on a front surface of the display device 100. The camera lens 120 is positioned in an upper region 115 of the front surface of the display device 100, separate from the display region 110. Having the upper region 115 with the camera lens 120 separate from the display region 110 limits the size, i.e., the active region, of the display region 110 of the display device 100.

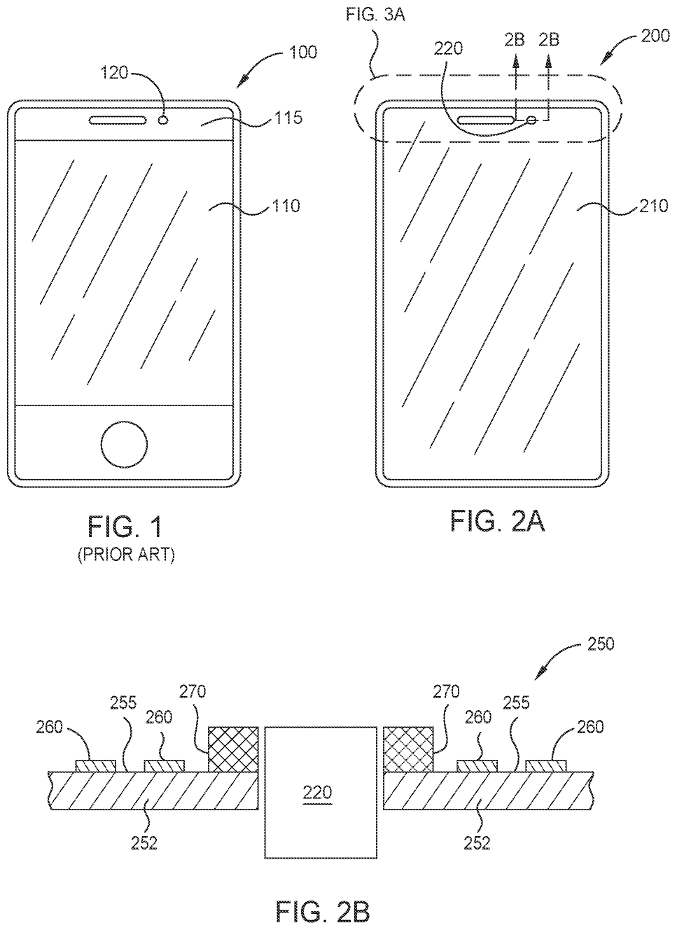

FIG. 2A is a schematic top view of a display device 200, e.g., a mobile phone, with electronic device accessory features, for example, a camera lens 220, integrated into an OLED display region 210 according to embodiments described herein. With device accessory features such as the camera lens 220 integrated into the display region 210, the display region 210 covers a larger area of a front surface of the display device 200. Thus, the display region 210 may cover the complete front surface, e.g., user facing surface, of the display device 200, as shown in FIG. 2A. Accordingly, the display device 200 having the display region 210 with integrated accessory features provides for an enhanced user experience, as compared to the display device 100 of FIG. 1, by fitting a larger display region 210 on the front surface of the same size device.

FIG. 2B is a schematic cross-sectional view formed along a cutting plane, 2B-2B, that extends through the integrated device accessory feature, camera lens 220, as shown in FIG. 2A. The display device 200 includes an OLED patterned substrate 250. The OLED patterned substrate 250 includes a substrate 252 having a top surface 255 with pre-formed OLED device structures 260 on the top surface 255 of the substrate 252. In one embodiment, the substrate 252 is made of glass or plastic, such as polyethyleneterephthalate (PET), polyethyleneterephthalate (PEN) or Polyimide (PI). The OLED patterned substrate 250 includes pre-formed wall 270. The wall 270 is provided on the top surface 255 of substrate 252 to provided support for an integrated device feature that is provided as part of the display region 210. In one example, the wall 270 is made of photo resist. In another example, the wall 270 is made of polyimide. In one embodiment, the wall 270 is configured to support and surround the camera lens 220, as shown in FIG. 2B. In another embodiment, the wall 270 is configured to support a sensor, such as an optical sensor or thermal sensor. In another embodiment, the wall 270 is configured to support a microphone or speaker.

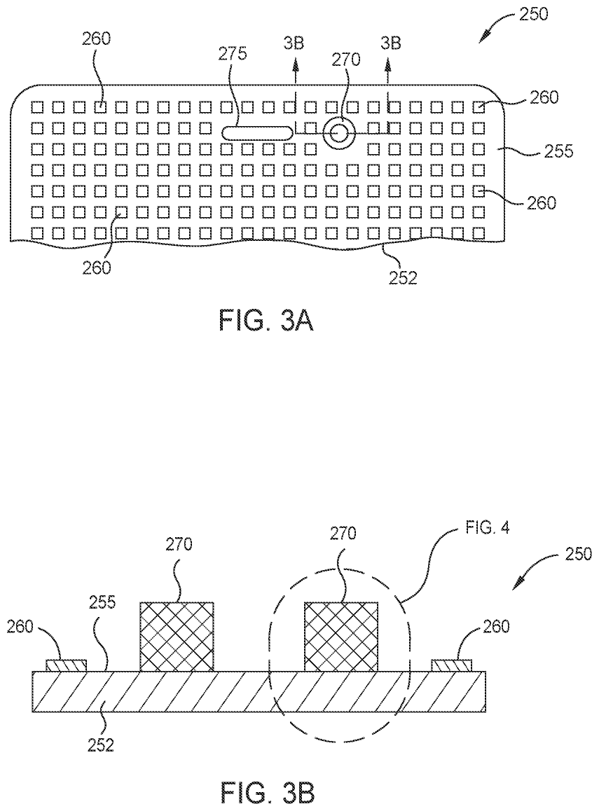

FIG. 3A is a top plan view of a portion of the OLED patterned substrate 250 found underneath a protective screen of the display region 210, as identified in FIG. 2A. FIG. 3B is a schematic cross-sectional view formed along a cutting plane, 3B-3B, that extends through a portion of the OLED patterned substrate 250 shown in FIG. 3A. The OLED patterned substrate 250 includes the plurality of OLED device structures 260 provided on the top surface 255 and includes the wall 270, e.g., a circular wall shown, configured to surround the camera lens 220. A slot 275 is provided to house, for example, a speaker for the display device 200. In some embodiments, the slot 275 is a slot shaped hole that passes through substrate 252. In some embodiments, not shown, the slot 275 is surrounded by a wall similar to the wall 270 to provide support for a speaker provided therein. In some embodiments, not shown, wall portions may be positioned on the substrate 252 in various locations to support additional device features such as microphones, speakers, and sensors. Referring to FIG. 3B, for clarity, the wall 270 is shown as the cross-section of the circular wall, showing two portions of the wall 270.

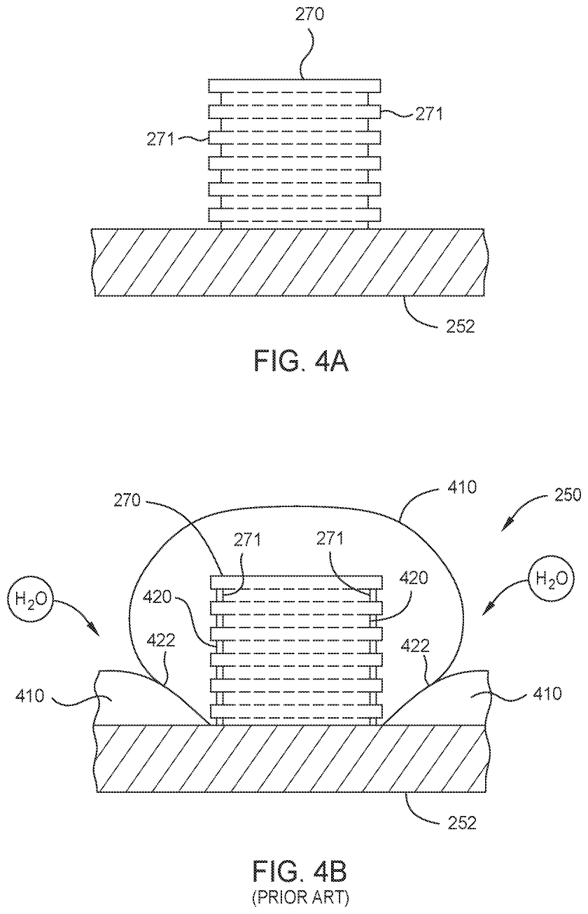

FIG. 4A is a schematic cross-section view of the wall 270 shown in FIG. 3B. The wall 270 is shown on substrate 252. As discussed above, the substrate 252 may be glass or plastic such as polyethyleneterephthalate (PET) or polyethyleneterephthalate (PEN) or Polyimide (PI). The wall 270 may be formed using common patterning methods used in semiconductor device manufacturing such as a pattern resist process using photolithography. The wall 270 may include multiple layers of polymer-based photoresist. Each of the layers may be deposited, cured and rinsed, and the process may repeated to form the wall 270 at a height and width as designed to support the integrated device accessory such as the camera lens 220 or a sensor. For example, in one embodiment, the wall 270 may have a height and width of 5 microns by 5 microns requiring dozens of layers of photoresist. In such an embodiment, because the photoresist is deposited in separate layers using a deposition, cure, rinse process, sidewalls 271 of the wall 270 are uneven leaving scalloped edged sidewalls 271, as shown FIG. 4A, providing a sidewall roughness of approximately 80-90 nm (peak to valley).

FIG. 4B is a schematic cross-sectional view of a conventional encapsulated wall portion formed from the wall portion shown in FIG. 4A. An encapsulation layer 410 is provided over the wall 270 and is also provided over the OLED device patterned substrate 250 and the OLED devices (not shown) to provide a barrier to moisture or oxygen ingress which limits the life of the OLED device patterned substrate and the OLED devices. The encapsulation layer 410 is a dielectric layer, such as SiN, SiON, SiO₂, Al₂O₃, AlN, or other suitable dielectric layer. The encapsulation layer 410 may be deposited by a suitable deposition technique, such as CVD, PVD, spin-coating, or other technique. The conventional encapsulation layer may have a thickness of about 0.1 μm to about 1.5 μm such as about 0.7 μm. In such conventional structures, the deposited encapsulation layer 410 leaves a plurality of voids 420 along the scallop shaped sidewalls 271. The voids 420 provide increased risk of degradation of the OLED patterned substrate 250 by providing for shortened pathways and defects allowing for the passage of moisture or oxygen to penetrate the encapsulation layer leading to the degradation of the OLED patterned substrate 250 and the OLED device structures 260. Additionally, seams 422 between the encapsulation layer 410 portion on the sidewall 271 and the encapsulation layer 410 portion on the OLED patterned substrate 250 provides for voids, gaps, and a shortened pathway for moisture and oxygen to infiltrate the encapsulation layer 410 and limit the life of the OLED patterned substrate 250.

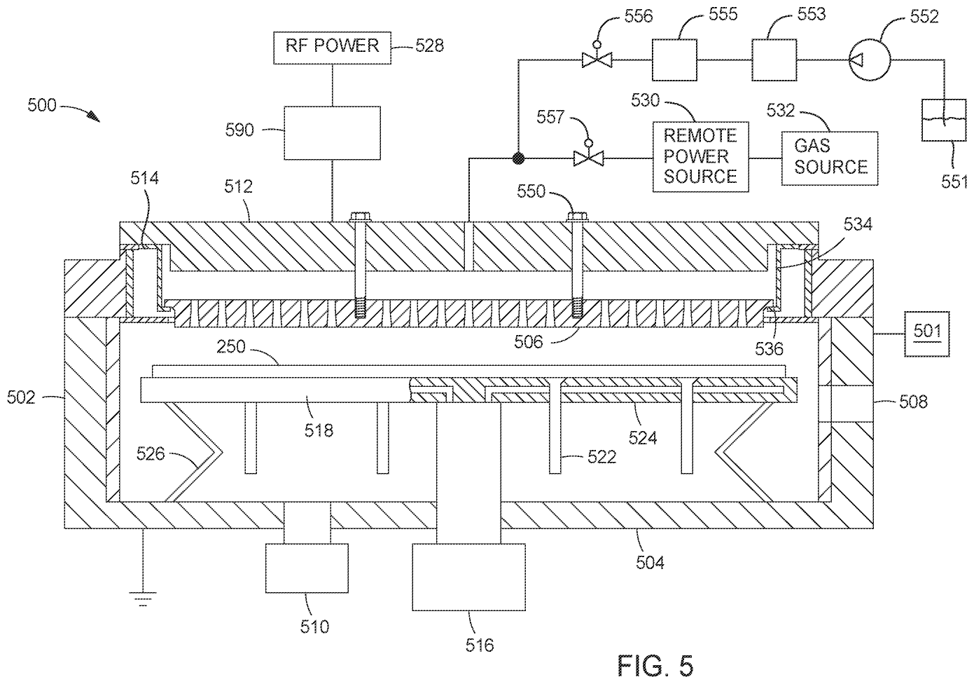

FIG. 5 is a schematic, cross sectional view of a plasma enhanced chemical vapor deposition (PECVD) apparatus that may be used to perform the operations described herein. The apparatus includes a chamber 500 in which one or more films may be deposited onto the OLED patterned substrate 250. The chamber 500 generally includes walls 502, a bottom 504, and a showerhead 506 which define a process volume. A substrate support 518 is disposed within the process volume. The process volume is accessed through a slit valve opening 508 such that the OLED patterned substrate 250 may be transferred in and out of the chamber 500. The substrate support 518 is coupled to an actuator 516 to raise and lower the substrate support 518. Lift pins 522 are moveably disposed through the substrate support 518 to move the OLED patterned substrate 250 to and from a substrate receiving surface of the substrate support 518. The substrate support 518 also includes heating and/or cooling elements 524 to maintain the substrate support 518 at a desired temperature. The substrate support 518 also includes RF return straps 526 to provide an RF return path at the periphery of the substrate support 518. The chamber 500 is connected to a system controller 501, the system controller is configured to store and/or implement aspects of the subject matter disclosed herein.

The showerhead 506 is coupled to a backing plate 512 by a fastening mechanism 550. The showerhead 506 is coupled to the backing plate 512 by one or more fastening mechanisms 550 to help prevent sag and/or control the straightness/curvature of the showerhead 506.

A gas source 532 is fluidly coupled via a valve 557 to the backing plate 512 to provide gas through gas passages in the showerhead 506 to a processing area between the showerhead 506 and the OLED patterned substrate 250. An ampoule 551 for suppling liquid precursors to the chamber 500 is connected to a pump 552, a fluid degasser 553, a vaporizer 555, and a valve 556. A vacuum pump 510 is coupled to the chamber 500 to maintain the process volume at a desired pressure. An RF source 528 is coupled through a match network 590 to the backing plate 512 and/or to the showerhead 506 to provide an RF current to the showerhead 506. The RF current creates an electric field between the showerhead 506 and the substrate support 518 so that a plasma may be generated from the gases between the showerhead 506 and the substrate support 518.

A remote plasma source 530, such as an inductively coupled remote plasma source, is coupled between the gas source 532 and the backing plate 512. Between processing substrates, a cleaning gas may be provided to the remote plasma source 530 so that a remote plasma is generated. Radicals from remote plasma generated by the remote plasma source 530 may be provided to the chamber 500 to clean chamber 500 components. The cleaning gas may be further excited by the RF source 528 provided to the showerhead 506.

The showerhead 506 is additionally coupled to the backing plate 512 by a showerhead suspension 534. In one embodiment, the showerhead suspension 534 is a flexible metal skirt. The showerhead suspension 534 may have a lip 536 upon which the showerhead 506 may rest. The backing plate 512 may rest on an upper surface of a ledge 514 coupled with the chamber walls 502 to seal the chamber 500.

The system controller 501 is configured to control the various components of chamber 500. The system controller 310 includes a programmable central processing unit (CPU) which is operable with a memory (e.g., non-volatile memory) and support circuits. The support circuits are conventionally coupled to the CPU and comprise cache, clock circuits, input/output subsystems, power supplies, and the like, and combinations thereof coupled to the various components of the chamber 500, to facilitate control thereof. The CPU is one of any form of general purpose computer processor used in an industrial setting, such as a programmable logic controller (PLC), for controlling various components and sub-processors of the additive manufacturing system 300. The memory, coupled to the CPU, is non-transitory and is typically one or more of readily available memories such as random access memory (RAM), read only memory (ROM), floppy disk drive, hard disk, or any other form of digital storage, local or remote.

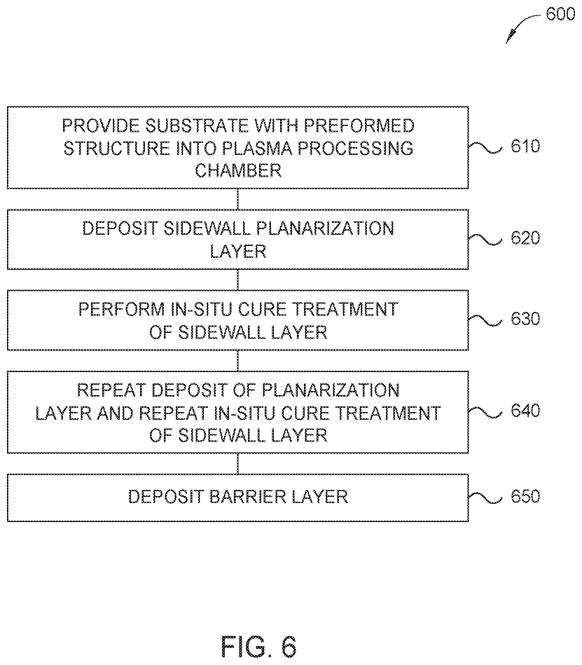

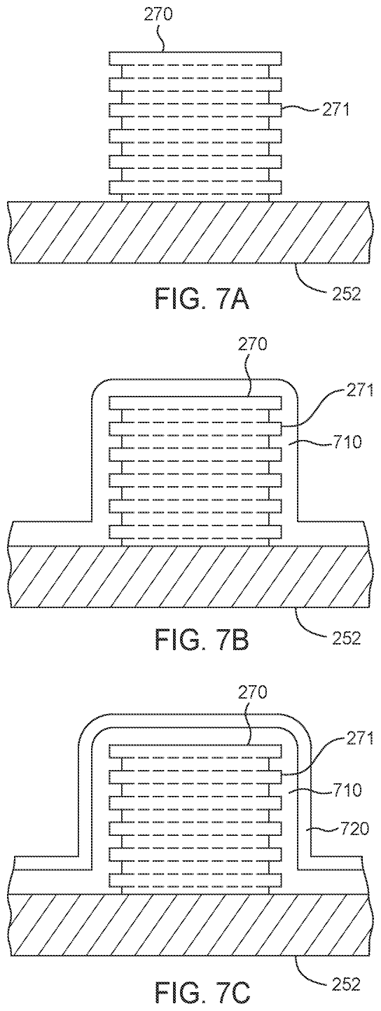

FIG. 6 is a flow diagram of a method 600 for encapsulating an OLED patterned substrate 250 in accordance with embodiments described herein. Although the method 600 operations are described in conjunction with FIGS. 5 and 7A-7C, persons skilled in the art will understand that any chamber configured to perform the method operations, in any order, falls within the scope of the embodiments described herein. Embodiments of the method 600 may be used in combination with one or more of chamber operations described herein, such as the chamber 500 of FIG. 5. The method 600 can be stored or accessible to the controller 501 as computer readable media containing instructions, that when executed by a processor of the controller 501, cause the chamber 500 to perform the method 600.

FIGS. 7A-7C illustrate schematic cross-sectional views of a wall 270 structure during different stages of the encapsulation method 600 of FIG. 6. The method 600 starts at process 610 by positioning an OLED patterned substrate 250 into a plasma processing chamber, such as processing chamber 500. The OLED patterned substrate 250 having OLED device structures, e.g., devices 260 (not shown), and a pre-formed wall 270 on the surface of the substrate 252, as shown in FIG. 7A, and similar to that discussed with reference to FIG. 3B.

At process 620 a sidewall planarization layer is deposited over the OLED patterned substrate 250 including wall 270 as shown in FIG. 7B. The sidewall planarization layer 710 provides a planarized interfacial layer that fills in one or more voids or gaps on the scalloped sidewalls 271 and overcomes the surface roughness of wall 270, creating a planarized sidewall layer over the sidewall 271 and the OLED patterned substrate 250 without voids or seams, thus minimizing the possibility of defects from moisture or oxygen. The sidewall planarization layer 710 may include fluorinated plasma-polymerized hexamethyldisiloxane (pp-HMDSO:F) and may be deposited in a PECVD chamber, such as chamber 500, providing superior particle coverage performance and surface planarization effect. The sidewall planarization layer 710 has a total thickness of between about 0.1 μm to about 1.0 μm such as between about 0.1 μm to about 0.3 μm to overcome the pattern sidewall roughness of approximately 80-90 nm (peak to valley). Deposition of the pp-HMDSO:F layer is achieved by flowing one or more fluorine-containing gases and HMDSO gas along with either O₂ or N₂O gas. The fluorine-containing gas may be nitrogen fluoride (NF₃), silicon fluoride (SiF₄), fluorine gas (F₂), carbon tetrafluoride (CF₄), or any combination thereof. The fluorine doped plasma polymerized HMDSO layer has superior particle coverage performance and surface planarization effect. The resulting sidewall planarization layer 710 has a fluorine content of less than 10 atomic percent.

During the deposition of the pp-HMDSO:F, the ratio of the flow rates of the fluorine-containing gas and the HMDSO gas may be between about 0.25 and about 1.5. The carbon content in the HMDSO may be greater than 10%. When depositing the sidewall planarization layer 710, the HMDSO is initially a liquid precursor provided from ampoule 551 but provides better coverage and uniformity when in a vapor state. Thus, the HMDSO is transformed into vapor by first flowing through the fluid degasser 553 and then flowing through the vaporizer 555 before delivery to the chamber 500. In one embodiment, the PECVD of the pp-HMDSO:F is performed under the following conditions. The SiF₄ has a flow rate of 125 standard cubic centimeters per minute (sccm) and HMDSO has a flow rate of 300 sccm. In other words, the ratio of SiF₄ to HMDSO is between about 0.40 to about 0.45. The plasma is generated at 700 W, and the chamber pressure is at about 1800 mtorr. The PECVD is deposited at about 80 degrees Celsius, and the distance between the OLED patterned substrate 250 and the showerhead 506 of the PECVD chamber 500 is between about 500-1200 mil, such as about 650 mil.

In one embodiment, a mask (not shown) is aligned over the OLED patterned substrate 250 such that the wall 270 is exposed through an opening in the mask. The mask is positioned such that the OLED device structures 260 are covered by the mask so that any subsequently deposited pp-HMDSO:F material deposits through the opening in the mask, but does not deposit on the OLED devices covered by the mask. The mask may be made from a metal material.

A sidewall planarization layer 710 comprising pp-HMDSO:F may have characteristics including stress relief, particle conformality, and flexibility. These characteristics of the pp-HMDSO:F sidewall planarization layer 710 allow the sidewall planarization layer 710 comprising pp-HMDSO:F to planarize surface irregularities to form a smooth surface. However, due to the formation process of the pp-HMDSO:F sidewall planarization layer, the pp-HMDSO:F sidewall planarization layer may be physically soft, which imposes an integration issue when stacked with the barrier layers, i.e., encapsulation layers. When a barrier layer stacks on top of a soft pp-HMDSO:F buffer layer, a wrinkled surface is formed. The wrinkled surface may create one or more voids and gaps creating defects susceptible to moisture ingress. In addition, the soft pp-HMDSO:F layer loses its optical transmittance, rendering the device unsuitable as a top emission OLED device.

In order to harden the sidewall planarization layer 710 and prevent a wrinkled surface from forming, plasma curing of the sidewall planarization layer 710 is performed. At process 630, the sidewall planarization layer 710 is cured in a vacuum environment. In one embodiment, the sidewall planarization layer 710 is cured in the same process chamber as the deposition of the sidewall planarization layer 710 (i.e., an in-situ curing process). The curing is performed using a mixed gas plasma, or a plasma produced from a gaseous mixture, that is configured to generate water (H2O) in the chamber in which the curing occurs. The mixed gas plasma is configured to generate water for condensation curing, which introduces moisture into the chamber. The mixed gas plasma may comprise two or more gases selected from the group of ammonia (NH3), nitrous oxide (N2O), hydrogen (H2), and oxygen (O2). For example, the mixed gas plasma may comprise NH3 and N2O, H2 and N2O, H2 and O2, or NH3 and O2. In one embodiment, the mixed gas plasma may further comprise fluorine, such as nitrogen fluoride (NF3), silicon fluoride (SiF4), fluorine gas (F2), and/or carbon tetrafluoride (CF4).

The ratio of the mixed gases in the mixed gas plasma depends on the spacing between the OLED patterned substrate 250 and a showerhead 506 of the processing chamber 500. For example, if the spacing between the OLED patterned substrate 250 and the showerhead 506 is about 650 mil, a 1:1 ratio of NH3 to N2O may be utilized for a curing duration of about 10-15 seconds. In another example, if the spacing between the OLED patterned substrate 250 and the showerhead is about 1000 mil, a 3:1 ratio of NH3 to N2O may be utilized for a curing duration of about 30 seconds. Thus, the curing duration depends on the ratio of the mixed gases in the mixed gas plasma and the spacing between the OLED patterned substrate 250 and the showerhead 506. As such, the curing duration may be increased to compensate for a higher ratio between the mixed gases of the mixed gas plasma and for a larger spacing between the OLED patterned substrate 250 and the showerhead 506. The hardened sidewall planarization layer 710 maintains its flexibility and optical transmittance as one or more buffer layers are subsequently deposited thereon.

In process 640, process 620 and process 630 are repeated one or more times to deposit one or more additional sidewall planarization layers 710 individually curing each deposited layer prior to depositing additional layers. Each additional layer maintains its flexibility and optical transmittance as one or more additional sublayers layers are subsequently deposited thereon.

The completed sidewall planarization layer 710 may have a thickness of about 0.1-1.0 μm. In one embodiment, it may take 1-10 additional layers deposited on the first cured sidewall planarization layer 710 to form the completed sidewall planarization layer 710 of the desired thickness. In another embodiment, the completed sidewall planarization layer 710 comprises 3 layers, each layer having a thickness of about 0.1 μm for a total thickness of 0.3 μm. The completed sidewall planarization layer 710 maintains its flexibility and overcomes the sidewall surface roughness providing a planarized surface for barrier layers subsequently deposited thereon.

At process 650 of method 600, a barrier layer, i.e., encapsulation layer, is deposited on the substrate over the sidewall planarization layer 710 to serve as a capping layer to protect the OLED device structure and patterned features such as wall 270 from moisture and oxygen. At process 650, barrier layer 720 is deposited on the sidewall planarization layer 710 and substrate 252, as shown in FIG. 7C. The barrier layer 720 is a dielectric layer, such as silicon nitride (SiN), silicon oxynitride (SiON), silicon dioxide (SiO2), or other suitable dielectric layers. The barrier layer 720 may have a thickness of between about 0.1 μm and 1.0 μm such as about 0.7 μm. The barrier layer 720 may be deposited by a suitable deposition technique, such as CVD, PECVD, physical vapor deposition (PVD), spin-coating, or other suitable technique. Additional barrier layers may added to further encapsulate and protect the OLED device patterned substrate and the features provided thereon.

The deposition of the sidewall planarization layer, the curing of the sidewall planarization layer, and the deposition of the barrier layers as described herein may be performed in a vacuum environment of a single deposition chamber, such as the PECVD chamber 500. Performing the deposition and curing operations in a vacuum environment of a single deposition chamber allows the sidewall planarization layer 710 and the barrier layer 720 to be formed without having to break vacuum, which eliminates or reduces delamination of the various layers, and further eliminates or reduces the risk of contaminates being introduced into the process chamber.

Purging of the process chamber 500 may be performed between deposition cycles to further minimize the risk of contamination. In one embodiment, the first sidewall planarization layer 710 is deposited and the chamber is then purged so the gases used for the deposition of the sidewall planarization layer are not present in the chamber for the subsequent curing process. As each layer of the plurality of layers of the sidewall planarization layer is deposited, the chamber 500 is purged and then the sidewall planarization layer is cured. The purge process is performed after each deposition and cure process until the desired thickness for the sidewall planarization layer is reached. The chamber may then be purged again so the gases used for the deposition and curation of the plurality of layers of the sidewall planarization layer are not present in the chamber for the subsequent barrier layer deposition process. In one embodiment, the chamber is not purged after the sidewall deposition process and is only purged after each curing process. Lastly, the barrier layer is deposited. The single chamber process may be advantageous in reducing cycle times as well as reducing the number of chambers (and equipment costs) of using a multiple chamber process.

In summary, an OLED patterned substrate for a display device is formed having a sidewall planarization layer filling scalloped voids along the sidewalls of the wall features of the OLED patterned substrate. The wall features are integrated into the OLED patterned substrate to provide support for additional display device features such as camera lens, speakers, microphones and sensors. The wall planarization layer may be multiple layers of pp-HMDSO:F with each layer cured before the next layer is formed. A barrier layer is formed over the sidewall planarization layer to protect the wall feature and OLED devices on the OLED patterned substrate from moisture and oxygen, which limit the life of the OLED devices. Furthermore, the sidewall planarization layer and barrier layers are deposited and cured in a vacuum environment of a single process chamber. Performing the deposition and curing operations in a vacuum environment of a single deposition chamber allows the sidewall planarization layer and barrier layer to be formed without ever having to break the vacuum, which further eliminates or reduces delamination and possible defects of the various layers. Additionally, the risk of contaminates being introduced into the process chamber is eliminated or reduced, which enables the sidewall planarization layer to maintain its flexibility and optical transmittance. Moreover, performing the deposition and curing operations in a vacuum environment of a single deposition chamber simplifies the method of formation of the encapsulated OLED patterned substrate, which may reduce associated costs.

While the foregoing is directed to embodiments of the present disclosure, other and further embodiments of the disclosure may be devised without departing from the basic scope thereof, and the scope thereof is determined by the claims that follow.

1. A method for forming an encapsulating structure on an organic light emitting diode (OLED) patterned substrate, comprising:
positioning an OLED patterned substrate into a plasma processing chamber, the OLED patterned substrate having a wall structure with at least one scalloped surface; and
depositing a sidewall planarization layer directly on the wall structure filling at least one of a plurality of voids along the at least one scalloped surface.

2. The method of claim 1, wherein depositing the sidewall planarization layer comprises flowing fluorinated plasma-polymerized hexamethyldisiloxane (pp-HMDSO:F).

3. The method of clam 1, further comprising:
curing the sidewall planarization layer using a mixed gas plasma in the processing chamber.

4. The method of claim 1, further comprising;
repeating the depositing the sidewall planarization layer.

5. The method of claim 4, further comprising: repeating the curing the sidewall planarization layer.

6. The method of claim 1, wherein the thickness of the sidewall planarization layer is between about 0.1 μm to about 1.0 μm.

7. The method of claim 1, wherein the sidewall planarization layer has a carbon content of greater that 10%.

8. The method of claim 2, wherein the fluorinated plasma-polymerized hexamethyldisiloxane (pp-HMDSO:F) flows through a degasser before entering the plasma processing chamber.

9. The method claim 8, wherein the fluorinated plasma-polymerized hexamethyldisiloxane (pp-HMDSO:F) flows from the degasser and through a vaporizer before entering the processing chamber.

10. The method of claim 1, further comprising forming a barrier layer on the sidewall planarization layer.

11. A patterned substrate comprising:
a substrate;
a plurality of organic light emitting diode (OLED) devices formed on a surface of the substrate;
at least one wall structure formed on the surface of the substrate, the wall structure having at least one scalloped surface; and
a sidewall planarization layer disposed over the wall structure and filling at least one of a plurality of voids along the at least one scalloped surface.

12. The patterned substrate of claim 11, wherein the sidewall planarization layer comprises fluorinated plasma-polymerized hexamethyldisiloxane (pp-HMDSO:F).

13. The patterned substrate of claim 12, wherein the sidewall planarization layer has a carbon content of greater than 10%.

14. The patterned substrate of claim 11, wherein the wall planarization layer is deposited directly on the at least one wall structure.

15. The patterned substrate of claim 11, wherein the wall structure is formed from multiple layers of resist material.

16. The patterned substrate of claim 15, wherein the at least one scalloped surface is formed by the multiple layers of the resist material.

17. The patterned substrate of claim 11, wherein the sidewall planarization layer is cured using a mixed gas plasma comprising at least NH₃ and N₂O.

18. (canceled)

19. The patterned substrate of claim 11, further comprising a barrier layer formed on the sidewall planarization layer.

20. A plasma processing chamber for forming an encapsulating structure on an organic light emitting diode (OLED) patterned substrate, the plasma processing chamber comprising:
a substrate support disposed within a processing region of the plasma processing chamber;
a showerhead disposed within the processing region opposite the substrate support;
a gas source coupled to the showerhead;
an ampoule configured to provide liquid precursors to the chamber; and
a controller configured to control the process for forming an encapsulation structure on the patterned substrate, the process comprising:
positioning an OLED patterned substrate into the plasma processing chamber, the OLED patterned substrate having a wall structure with at least one scalloped surface; and
depositing a sidewall planarization layer directly on the wall structure filling at least one of a plurality of voids along the at least one scalloped surface.

21. The plasm a processing chamber of claim 20, wherein the process further comprises forming a barrier layer on the sidewall planarization layer.
